(19) United States
(12) Patent Application Publication
(10) Pub. No.: US 2021/0265176 A1
(43) Pub. Date: Aug. 26, 2021

(54) SUBSTRATE PROCESSING APPARATUS AND METHOD FOR FABRICATING CATALYST PROCESSING MEMBER

(71) Applicant: EBARA CORPORATION, Tokyo (JP)

(72) Inventors: Atsuo Katagiri, Tokyo (JP); Itsuki Kobata, Tokyo (JP)

(21) Appl. No.: 17/180,394

(22) Filed: Feb. 19, 2021

(30) Foreign Application Priority Data
Feb. 26, 2020 (JP) 2020-030590

(51) Int. Cl. H01L 21/67

(52) U.S. Cl. CPC H01L 21/6708

(57) ABSTRACT

A substrate processing apparatus includes a stage for holding a wafer, a catalyst processing member for processing the surface of the wafer using a catalyst, a pressing mechanism for pressing the catalyst processing member against the wafer, a relative motion mechanism for causing the catalyst processing member and the wafer to make a relative movement, and a supply mechanism for supplying a process liquid to the surface the wafer. The catalyst processing member has a processing surface opposed to the wafer, and includes a base material on which a groove is formed on the processing surface and the catalyst. The processing surface of the base material includes a plurality of regions sectioned by the groove. The catalyst processing member holds different types of catalysts in the plurality of regions.

### TECHNICAL FIELD

This application relates to a substrate processing apparatus and a method for fabricating a catalyst processing member. This application claims priority from Japanese Patent Application No. 2020-030590 filed on Feb. 26, 2020. The entire disclosure including the descriptions, the claims, the drawings, and the abstracts in Japanese Patent Application No. 2020-030590 is herein incorporated by reference.

### BACKGROUND ART

In manufacturing processes of semiconductor devices, a chemical mechanical polishing (CMP) for processing a surface of a substrate has been widely used. A CMP apparatus polishes the surface of the substrate by having a polishing head holding the substrate as a process target, pressing the substrate against a polishing pad installed on a polishing table, and causing the polishing head and the polishing table to make relative movement while supplying a slurry between the polishing pad and the substrate.

In association with miniaturization of current semiconductor device structures, a planarization technique with higher accuracy, a processing accuracy in an angstrom order, and a processing technique without any damage have been demanded. The planarization process typified by the CMP is no exception. While a removal amount itself decreases to, for example, around 100 Å, in association with the miniaturization, controllability at an atomic level is required. In order to satisfy this requirement, catalyst referred etching (CARE) as described in PTL 1 has been proposed as a novel processing technique. In the CARE method, in the presence of a process liquid, a reactive species with a surface to be processed is generated from inside the process liquid only near a catalyst material, and the catalyst material and the surface to be processed are brought close or into contact. Thus, the CARE method ensures selectively causing an etching reaction of the surface to be processed on the surface close to or in contact with the catalyst material. For example, for a surface to be processed that has unevenness, bringing the protruding portions close to or into contact with the catalyst material ensures selectively etching the protruding portions, thereby ensuring a planarization of the surface to be processed.

A substrate processing apparatus employing the CARE technique includes a stage for upwardly holding a surface to be processed of a substrate and a catalyst holding member configured to hold a catalyst for processing the surface to be processed of the substrate. The substrate processing apparatus, while supplying a process liquid to the substrate and bringing the catalyst holding member into contact with the surface to be processed of the substrate, causes the catalyst holding member and the substrate to make a relative movement. As a result, the reactive species generated on the catalyst surface and the substrate cause a chemical reaction to remove a material on the substrate surface.

### CITATION LIST

### Patent Literature

PTL 1: WO2015/159973

### SUMMARY OF INVENTION

### Technical Problem

In the substrate processing apparatus as described in PTL 1, the catalyst holding member has been configured by depositing a catalyst on an elastic body using a sputtering method, a plating method, a vapor deposition method, a chemical vapor deposition method, or the like.

While in the conventional method, an etching removal has been performed by depositing a single catalyst on an elastic base material by the above-described method and sliding the obtained catalyst with a process target on the surface to be processed of the substrate, it has been known that some elements are easy to etch and some elements are hard to etch depending on types of catalysts. From such a reason, a process target in which different metals are mixed is difficult to be planarized and removed at a uniform processing speed with the single catalyst using the CARE method. While the catalyst holding member of an elastic body, such as a rubber, on which a catalyst is deposited, makes sliding contact with the process target in the presence of a chemical liquid, when a catalyst deposited on a smooth elastic base material in particular without any processing thereon is used, it is known that the etching caused by the CARE reaction does not progress especially at the center of the catalyst. The cause of this is considered that the reaction chemical liquid is not sufficiently supplied to the catalyst and near the process target. With this aspect, since the reaction is not uniform in the catalyst contact portion, uniformity in a plane of the material to be worked may be disturbed.

Since the catalyst deposited on the elastic body has a thickness in nanometer order, bringing the elastic body after the catalyst deposition into contact with the substrate and sliding it may delaminate or wear the catalyst film due to expansion and contraction of the elastic body to possibly dissipate the catalyst on the elastic body. Additionally, difference in thermal shrinkage rates between the catalyst after the deposition and the elastic body possibly generates minute bumps on the catalyst film or the delaminated catalyst possibly leaves scratch marks on the substrate. Thus, performing the processing using the conventional catalyst holding member may delaminate the catalyst from the elastic body to possibly break the substrate itself or damage the surface to be processed of the substrate. These breakage and damage directly affect the performance of the device, and therefore, their reduction is necessary.

Furthermore, catalysts are considered to have different reactivity depending on the crystalline structure, the crystal orientation, and the crystallinity, and many depositing methods are often suitable for a fabrication under a high temperature of several hundred degrees in order to obtain a catalyst with high crystallinity. However, as has been performed in the CARE so far, when a catalyst film is formed on the elastic body, the film formation at a temperature around room temperature has been inevitable in consideration of the heat-resistant temperature of the elastic body, and thus, it has been difficult to manipulate the crystalline structure and obtain a catalyst film with high crystallinity. Directly depositing a film on an elastic body having much unevenness on the surface makes a catalyst reference surface a surface in accordance with a configuration of the base material. This is not a preferred condition for applying a catalyst referred etching, and therefore, an improvement is necessary.

Therefore, an object of this application is to solve at least one of the above-described problems in a substrate processing apparatus employing the CARE technique, and an exemplary object is to uniformly planarize and remove heterogeneous films.

### Solution to Problem

According to one embodiment, there is disclosed a substrate processing apparatus including: a stage for holding a substrate with a surface to be processed upward; a catalyst processing member for processing the surface to be processed of the substrate using a catalyst; a pressing mechanism for pressing the catalyst processing member against the surface to be processed of the substrate; a relative motion mechanism for causing the catalyst processing member and the substrate to make a relative movement; and a supply mechanism for supplying a process liquid to the surface to be processed of the substrate; wherein the catalyst processing member has a processing surface opposed to the surface to be processed of the substrate, and includes a base material on which a groove in a grid shape, a radial shape, a concentric shape, or a shape composed thereof is formed on the processing surface and the catalyst held on the processing surface, the processing surface of the base material includes a plurality of regions sectioned by the groove, and the catalyst processing member holds different types of catalysts in the plurality of regions.

### BRIEF DESCRIPTION OF DRAWINGS

FIG. 1 is a schematic plan view illustrating a schematic configuration of a substrate processing apparatus as one embodiment of the present invention;

FIG. 2 is a side view of the substrate processing apparatus illustrated in FIG. 1;

FIG. 3 is a drawing schematically illustrating a catalyst processing member as one embodiment;

FIG. 4 is a drawing schematically illustrating a catalyst processing member as one embodiment:

FIG. 5 is a drawing schematically illustrating a catalyst processing member as one embodiment:

FIG. 6 is a drawing schematically illustrating a catalyst processing member as one embodiment;

FIG. 7 is a schematic cross-sectional side view illustrating a catalyst processing member 30 in a state of being mounted on a swing arm as one embodiment:

FIG. 8 is a schematic diagram illustrating a configuration for controlling a force for pressing the catalyst processing member 30 against a surface to be processed of a wafer W using the swing arm as one embodiment:

FIG. 9 is a flowchart illustrating a procedure to PID control a contact pressure between a catalyst holding member and the wafer W as one embodiment;

FIG. 10 is a drawing illustrating a method for fabricating a catalyst processing member as one embodiment:

FIG. 11 is a drawing illustrating a method for fabricating the catalyst processing member as one embodiment;

FIG. 12 is a plan view illustrating a schematic configuration of a substrate processing system as one embodiment:

FIG. 13 is a graph illustrating removal rates when a Ru film formed on a surface to be processed of a wafer is planarized using various kinds of catalysts under a condition where a chemical liquid has pH=12:

FIG. 14 is a graph illustrating removal rates when a TiN film formed on a surface to be processed of a wafer is planarized using various kinds of catalysts under a condition where a chemical liquid has pH=12:

FIG. 15 is a graph illustrating removal rates when a TEOS film formed on a surface to be processed of a wafer is planarized using various kinds of catalysts under a condition where a chemical liquid has pH=12;

FIG. 16 is a graph illustrating removal rates when a Ru film formed on a surface to be processed of a wafer is planarized using various kinds of catalysts under a condition where a chemical liquid has pH=1;

FIG. 17 is a graph illustrating removal rates when a TiN film formed on a surface to be processed of a wafer is planarized using various kinds of catalysts under a condition where a chemical liquid has pH=1;

FIG. 18 is a graph illustrating removal rates when a TEOS film formed on a surface to be processed of a wafer is planarized using various kinds of catalysts under a condition where a chemical liquid has pH=1; and

FIG. 19 is a graph illustrating removal rates when a Co film formed on a surface to be processed of a wafer W is planarized using various kinds of catalysts under a condition where a chemical liquid has pH=12;

### DESCRIPTION OF EMBODIMENTS

The following describes embodiments of a substrate processing apparatus and a method for fabricating a catalyst processing member according to the present invention with the attached drawings. In the attached drawings, identical or similar reference numerals are attached to identical or similar components, and overlapping description regarding the identical or similar components may be omitted in the description of the respective embodiments. Features illustrated in the respective embodiments are applicable to other embodiments in so far as they are consistent with one another.

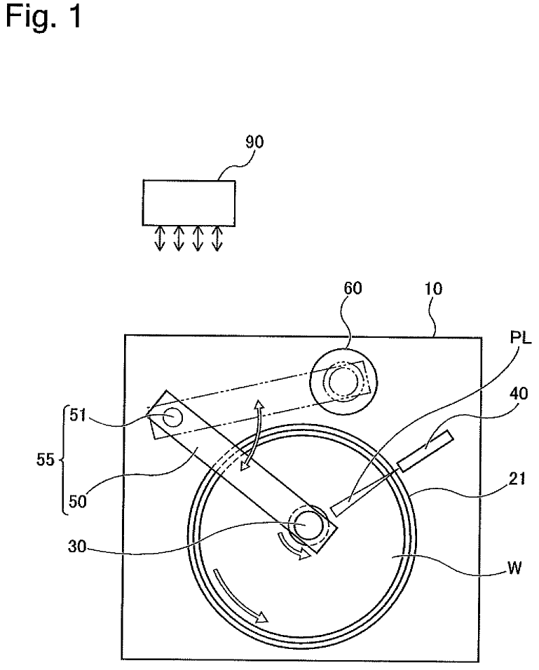

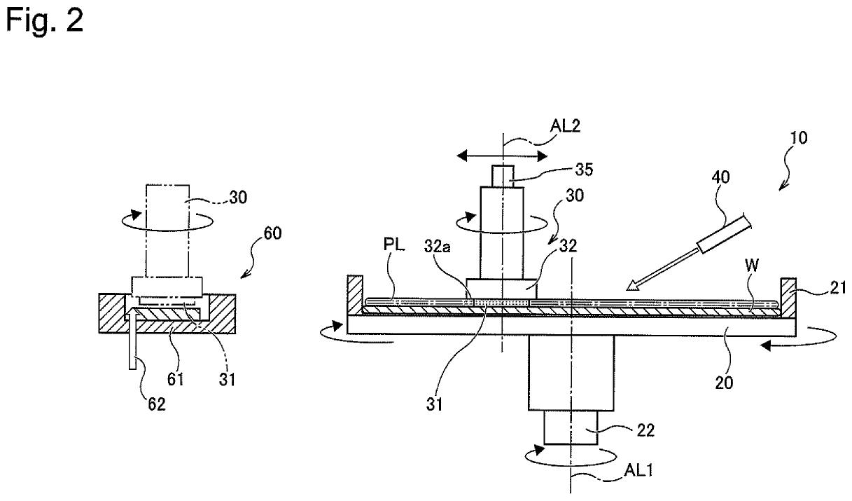

FIG. 1 is a schematic plan view illustrating a schematic configuration of a substrate processing apparatus 10 as one embodiment of the present invention. FIG. 2 is a side view of the substrate processing apparatus 10 illustrated in FIG. 1. The substrate processing apparatus 10 is an apparatus configured to perform an etching process of a semiconductor material (region to be processed) on a substrate using the CARE method.

The substrate processing apparatus 10 includes a stage 20, a catalyst processing member 30, a process liquid supply member 40, a swing arm 50, a conditioning member 60, and a controller 90. The stage 20 is configured to hold a wafer W as one type of substrates. In this embodiment, the stage 20 holds the wafer W such that a surface to be processed (a surface to be polished) of the wafer W faces upward. In this embodiment, the stage 20 includes a vacuum suction mechanism for vacuum suctioning a back surface (a surface on the opposite side of the surface to be polished) of the wafer W as a mechanism for holding the wafer W. For a method for vacuum suctioning, any one of the method of point suctioning using a suction plate having a plurality of suction holes coupled to a vacuum line on a suction surface or the method of surface suctioning that has grooves (for example, concentric) on a suction surface and suctions through connection holes to a vacuum line provided in the groove may be used. In order to stabilize a suction state, a backing material may be attached on a surface of the suction plate and the wafer W may be suctioned via the backing material.

The stage 20 is configured to be rotatable about an axis line AL1 by a rotation drive mechanism 22, such as a motor. In this drawing, the stage 20 includes a wall member 21 that extends upwardly in a vertical direction across a whole circumferential direction outside with respect to a region for holding the wafer W. In view of this, the process liquid can be held in a wafer plane, thereby ensuring a reduced usage of the process liquid. Note that, while in this drawing, the wall member 21 is secured on an outer periphery of the stage 20, it may be configured in a separate body from the stage 20. In such a case, the wall member 21 may move vertically. Allowing the vertical motion ensures changing a retention amount of the process liquid and ensures efficiently discharging a cleaning liquid out of the wafer W by lowering the wall member 21 when, for example, the substrate surface after the etching process is cleaned.

The catalyst processing member 30 in the embodiment illustrated in FIG. 1 and FIG. 2 is a member for processing the surface to be processed of the wafer W using a catalyst 31. The catalyst processing member 30 is configured by including a base material 32 having a processing surface 32a opposed to the surface to be processed of the wafer W and the catalyst 31 in a form of a foil, a film, or a plate with a micrometer order thickness held by the processing surface 32a. The catalyst processing member 30 can attach the foil, film, or plate-form catalyst 31 on the processing surface 32a using, for example, an adhesive. The catalyst 31 may be a metallic foil or a metallic film, and in this case, a single metal or an alloy made of two or more elements can be employed. The base material 32 is configured of an elastic body, such as a rubber or a sponge. In this embodiment, the catalyst 31 is smaller than the wafer W. That is, a projected area of the catalyst 31 when projected from the catalyst 31 toward the wafer W is smaller than an area of the wafer W. The catalyst processing member 30 is configured to be rotatable about an axis line AL2 by a rotation drive mechanism 35, such as a rotation motor 50-10 described later. The rotation drive mechanism 22 and the rotation drive mechanism 35 configure a relative motion mechanism for causing the catalyst processing member 30 and the wafer W to make a relative movement.

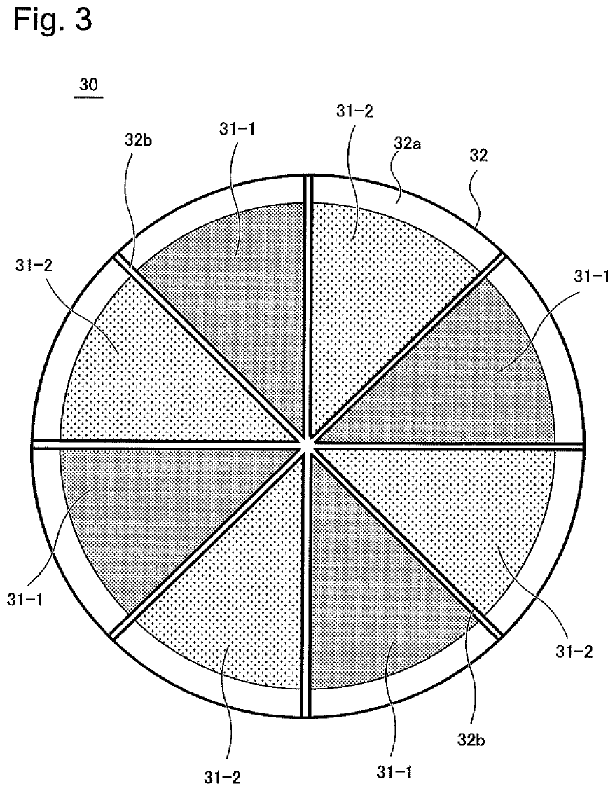

FIG. 3 to FIG. 6 are drawings schematically illustrating catalyst processing members as one embodiment. As illustrated in FIG. 3, on the processing surface 32a of the base material 32, radial grooves 32b are formed. This forms six regions sectioned by the grooves 32b on the processing surface 32a. The catalyst processing member 30 holds different types of catalysts, instead of holding a single catalyst in the six regions. Specifically, the catalyst 31 includes a first catalyst 31-1 and a second catalyst 31-2. The catalyst processing member 30 holds the first catalyst 31-1 and the second catalyst 31-2 alternately in a circumferential direction in portions where the grooves 32b are absent on the processing surface 32a, that is, in the six regions. The embodiment according to FIG. 3 ensures changing an area ratio of the first catalyst 31-1 to the second catalyst 31-2 by changing angles of central angles of the six regions.

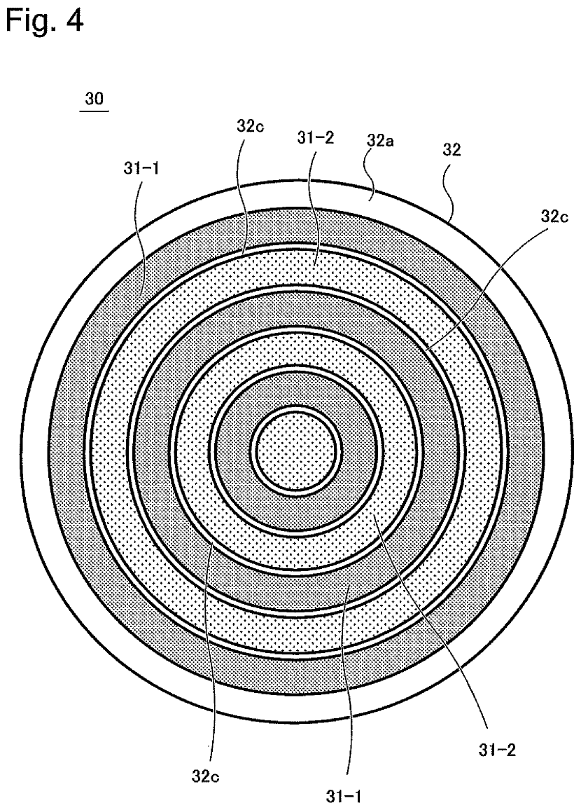

As illustrated in FIG. 4, on the processing surface 32a of the base material 32, concentric grooves 32c may be formed. This forms six regions sectioned by the grooves 32c on the processing surface 32a. In this case, the catalyst processing member 30 can hold the first catalyst 31-1 and the second catalyst 31-2 alternately in a radial direction in portions where the grooves 32c are absent on the processing surface 32a, that is, in the six regions. The embodiment illustrated in FIG. 4 ensures making scratch and delamination of the catalyst 31 less likely to occur since end portions of the grooves are not positioned in the rotation direction of the catalyst processing member 30.

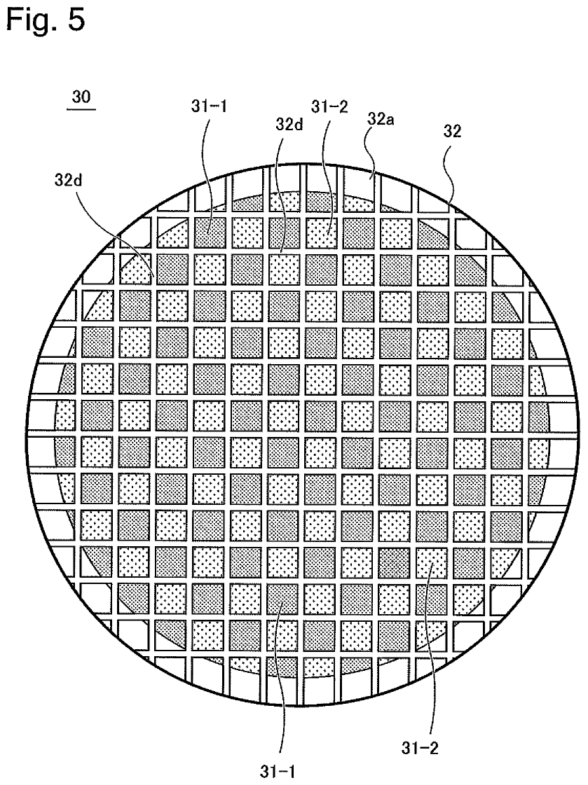

As illustrated in FIG. 5, on the processing surface 32a of the base material 32, grid-shaped (lattice-shaped) grooves 32d may be formed. This forms many regions sectioned by the grooves 32d on the processing surface 32a. In this case, the catalyst processing member 30 can hold the first catalyst 31-1 and the second catalyst 31-2 alternately in a longitudinal direction and a lateral direction in portions where the grooves 32d are absent on the processing surface 32a, that is, in the many regions. The embodiment illustrated in FIG. 5 ensures a uniformed abundance ratio of the second catalyst 31-2 to the first catalyst 31-1 per small region of the processing surface 32a. Additionally, the embodiment illustrated in FIG. 5 ensures uniformly flowing the process liquid supplied from the center of the catalyst processing member 30 over the entire processing surface 32a (catalyst) quickly since the grooves 32d are formed in a grid shape (lattice shape) on the processing surface 32a, and this ensures a quick removal of a process target object of the wafer W.

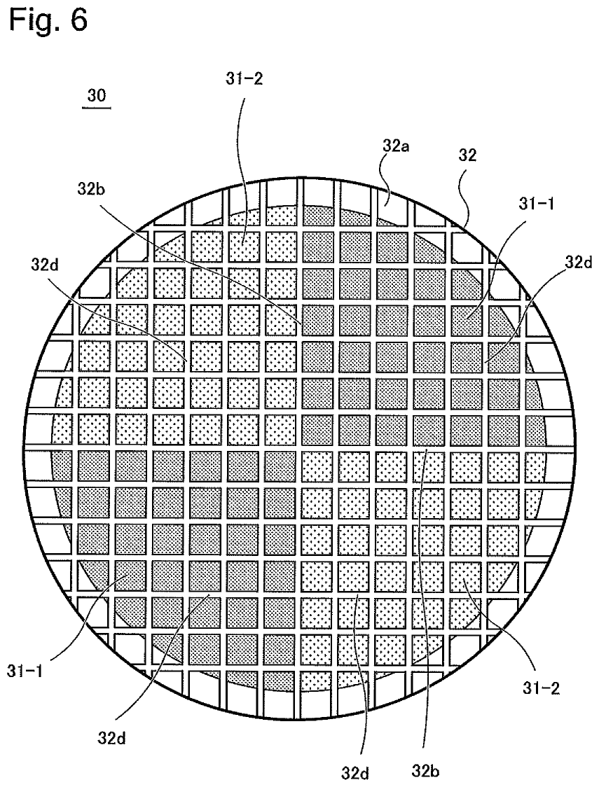

Furthermore, as illustrated in FIG. 6, on the processing surface 32a of the base material 32, the grooves 32b radially extending from the center of the base material 32 (grooves 32d extending in up-down and right-left directions passing through the center of the base material 32) may be formed, and the grid-shaped grooves 32d for each of four regions sectioned by the radial grooves 32b may be formed. This forms the four regions sectioned by the grooves 32b and forms many regions sectioned by the grooves 32d for each of the four regions on the processing surface 32a. In this case, the catalyst processing member 30 ensures holding the first catalyst 31-1 and the second catalyst 31-2 alternately in the circumferential direction for the four regions sectioned by the radial grooves 32b. The embodiment illustrated in FIG. 6 ensures flowing the process liquid over the entire processing surface 32a quickly, similarly to the embodiment illustrated in FIG. 5, and ensures easily fabricating the catalyst processing member 30.

Note that, not limited to the patterns of grooves illustrated in the embodiments illustrated in FIG. 3 to FIG. 6, grooves in grid shape, concentric shape, radial shape, or any shape obtained by combining them can be formed on the processing surface 32a. While this embodiment has illustrated the example where the catalyst 31 includes two types of catalysts (the first catalyst 31-1 and the second catalyst 31-2), it is not limited to this, and the catalyst 31 can include any number or types of catalysts corresponding to the number or type of the process target material on the surface to be processed of the wafer W. Furthermore, while this embodiment has illustrated the example where the catalyst processing member 30 holds the first catalyst 31-1 and the second catalyst 31-2 in equal proportion, it is not limited to this, and different types of catalysts can be held on the processing surface 32a at an area ratio corresponding to an area ratio of a plurality of the process target materials on the surface to be processed of the wafer W.

Since the catalyst processing member 30 holds the catalyst 31 having the thickness in micrometer order, the embodiments illustrated in FIG. 3 to FIG. 6 ensure gaining time until the catalyst 31 dissipates due to the wear and ensure maintaining a life of the catalyst 31 compared with the related art. Furthermore, with the embodiments illustrated in FIG. 3 to FIG. 6, since bonding between the catalyst 31 and the base material 32 becomes strong, the catalyst 31 is hardly delaminated from the base material 32 even though the catalyst processing member 30 is brought into contact with the wafer W and slid, and therefore an occurrence of breakage of the wafer W and damage on the surface to be processed can be reduced. While the metallic catalyst is considered to have different reaction rates depending on its crystalline structure and crystal orientation, separately fabricating the catalyst instead of directly depositing the catalyst on the base material enables not only to manipulate the crystalline structure of the catalyst, the crystallinity of the catalyst, and the crystal orientation with respect to the reference surface with, for example, any heating process allowed by the catalyst fabrication process, but also to provide any process, such as smoothing the catalyst surface and modifying the catalyst surface. This substantially reduces factors affected by a material, a surface condition, a heat-resistant temperature, or the like of the base material compared with the conventional case of directly forming a film on an elastic base material, and ensures obtaining the catalyst processing member 30 including a catalyst of certain quality.

The embodiments illustrated in FIG. 3 to FIG. 6 ensures uniformly planarizing and removing a plurality of the process target materials (heterogeneous films) on the surface to be processed of the wafer W at an equal removal rate. That is, since, in most of the cases, the material of the process target object has a different removal rate depending on the catalyst, it is possible that the process target object cannot be uniformly removed w % ben the catalyst present on the processing surface 32a of the base material 32 is of one type. In contrast to this, in the embodiments illustrated in FIG. 3 to FIG. 6, the catalyst 31 of two or more types is provided on the processing surface 32a corresponding to the process target objects present on the surface to be processed of the wafer W, and their abundance ratio is adjusted, thereby ensuring removing each of the process target objects at an equal removal rate.

The embodiments illustrated in FIG. 3 to FIG. 6 ensures making a problem that an inside of a pattern on the surface to be processed of the wafer W is etched less likely to occur. That is, when the wafer W as the process target has fine grooves (patterns) having a nanometer order depth and a planarization process is attempted in order to eliminate these level differences, there has occurred a problem that the inside of the groove is also etched due to the base material getting into the inside of the fine groove since the base material on which the catalyst is deposited has elasticity in the catalyst processing member of the related art. In contrast to this, in the embodiments illustrated in FIG. 3 to FIG. 6, the foil, film, or plate-form catalyst 31 with a micrometer order thickness is provided on the processing surface 32a of the base material 32, a minute deformation of the base material 32 can be avoided, and as a result, the problem that the inside of the pattern on the surface to be processed of the wafer W is etched can be made less likely to occur.

As illustrated in FIG. 1 and FIG. 2, the process liquid supply member 40 is configured to supply a process liquid PL on the surface of the wafer W. Here, while there is one process liquid supply member 40 in the drawings, a plurality of the process liquid supply members 40 may be arranged, and, for example, a plurality of the process liquids may be used for individual materials when a plurality of materials of the process target are mixed on the surface to be processed of the wafer W. In such a case, the different process liquids may be supplied from the respective process liquid supply members. Here, the process liquid can be, for example, an ozone water, an acid, an alkaline solution, a H₂O₂ water, a hydrofluoric acid solution, and their combination. When the wafer W surface is cleaned in this substrate processing apparatus 10 after the etching process, a cleaning chemical liquid or water may be supplied from the process liquid supply member 40. The process liquid supply member 40 may be secured to the swing arm 50 at the proximity of the catalyst processing member 30, preferably, at an upstream portion of the rotation of the wafer W, that is, at a position where the process liquid supplied from the process liquid supply member 40 is efficiently supplied to the catalyst processing member 30 by the rotation of the wafer W. In this case, the process liquid supply member 40 is configured to move with the catalyst processing member 30. Such a configuration ensures always supplying the fresh process liquid PL to near the catalyst 31, and as a result, the etching performance is stabilized. Despite the configuration of swing movement by the swing arm 50 of the catalyst processing member 30, the process liquid can be supplied to the proximity of a contact portion between the catalyst 31 and the wafer W and the usage of the process liquid can be reduced.

The substrate processing apparatus 10 includes a swing mechanism 55 for swinging the catalyst processing member 30 in the radial direction of the wafer W. The swing mechanism 55 includes the swing arm 50 that holds the catalyst processing member 30 and a rotation shaft 51 that swingably holds the swing arm 50. The swing arm 50 is configured to be swingable about the rotation shaft 51 by a rotation drive mechanism (not illustrated), such as a motor, and configured to be vertically movable. The swing arm 50 has a distal end (an end portion on the opposite side of the rotation shaft 51) where the catalyst processing member 30 is rotatably mounted. Here, since etching occurs only in the contact portion with the catalyst in this CARE method, a wafer in-plane distribution of a contact period of the wafer W with the catalyst 31 largely affects a wafer in-plane distribution of an etching amount. Regarding this, the distribution of the contact period can be uniformized by making the swing speed in the wafer plane of the swing arm 50 variable. Specifically, a swing range of the swing arm 50 in the wafer W plane is divided into a plurality of sections, and the swing speeds are controlled in the respective sections.

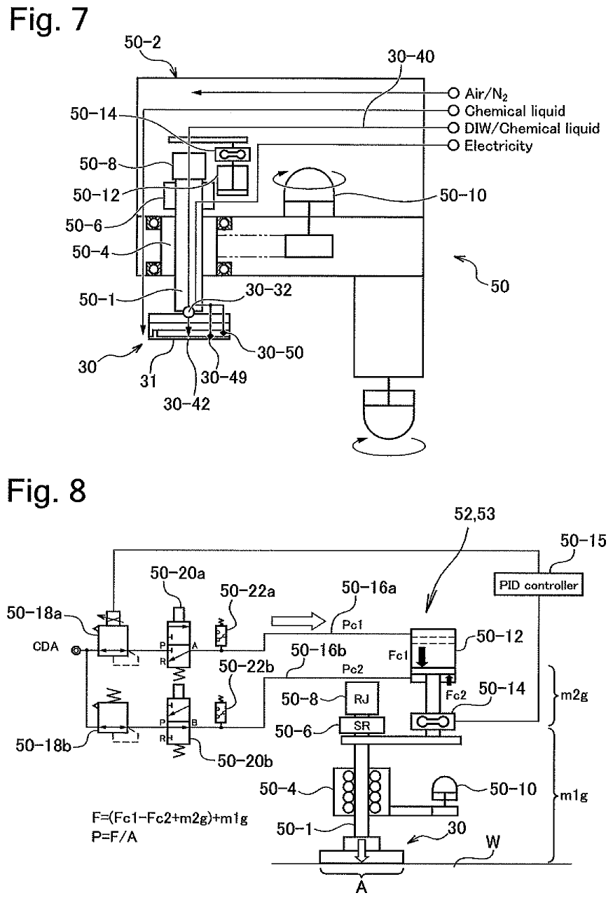

As one embodiment, the catalyst processing member 30 disclosed herein can be mounted on the swing arm 50. FIG. 7 is a schematic cross-sectional side view illustrating the catalyst processing member 30 in a state of being mounted on the swing arm 50 as one embodiment. As illustrated in FIG. 7, the swing arm 50 is entirely surrounded by a cover 50-2. The catalyst processing member 30 is coupled to a shaft 50-1 via a gimbal mechanism 30-32. The shaft 50-1 is rotatably supported by a ball spline 50-4, a slip ring 50-6, and a rotary joint 50-8. Note that, instead of the slip ring 50-6, a rotary connector may be used, or an electrical connection may be achieved in a non-contact manner.

The catalyst processing member 30 can be rotated by the rotation motor 50-10. The shaft 50-1 is axially driven by an elevating air cylinder 50-12. For the air cylinder 50-12, an air bearing cylinder can be used. Using the air bearing cylinder reduces sliding resistance, and can also reduce hysteresis. The air cylinder 50-12 is coupled to the shaft 50-1 via a load cell 50-14. The load cell 50-14 can measure the force applied from the air cylinder 50-12 to the shaft 50-1.

The swing arm 50 has a process liquid supply passage 30-40 so as to be able to supply the process liquid and/or water from a supply port 30-42 on the surface of the catalyst 31 of the catalyst processing member 30. The process liquid and/or water may be supplied from outside the catalyst processing member 30. The swing arm 50 is connected to a supply source of air or nitrogen, and can be configured to supply the air or nitrogen into the cover 50-2. Since a chemical liquid with high corrosivity is sometimes used in the CARE process, the inside of the cover 50-2 can have an air pressure higher than an external air pressure to prevent the process liquid PL from entering inside the cover 50-2.

A catalyst electrode 30-49 is arranged so as to be electrically coupled to the catalyst 31. On the other hand, a counter electrode 30-50 is arranged so as to be able to apply a voltage to the catalyst 31 via the process liquid PL. The voltage can be applied to the catalyst electrode 30-49 and the counter electrode 30-50 by an external power source. In the CARE method, the etching rate is adjustable by an applied voltage between the catalyst electrode 30-49 and the counter electrode 30-50.

FIG. 8 is a schematic diagram illustrating a configuration for controlling force to press the catalyst processing member 30 against the surface to be processed of the wafer W using the swing arm 50 as one embodiment. As illustrated in FIG. 8, the substrate processing apparatus 10 includes a pressing mechanism 52 for pressing the catalyst processing member 30 against the surface to be processed of the wafer W. In the embodiment in FIG. 8, the pressing mechanism 52 includes an elevating mechanism 53 for elevating the catalyst processing member 30. The elevating mechanism 53 specifically includes the air cylinder 50-12, an electropneumatic regulator 50-18a, a precision regulator 50-18b, a PID controller 50-15, and the like.

A piston of the air cylinder 50-12 has one side to which a first pipe passage 50-16a for supplying the air is connected. The first pipe passage 50-16a is connected to the electropneumatic regulator 50-18a, a solenoid valve 50-20a, and a pressure gauge 50-22a. The electropneumatic regulator 50-18a is connected to the PID controller 50-15, and converts an electric signal received from the PID controller 50-15 into an air pressure. The solenoid valve 50-20a is a normally closed valve, and the air flows through it when it is ON. The pressure gauge 50-22a can measure the pressure in the first pipe passage 50-16a. The piston of the air cylinder 50-12 has the other side to which a second pipe passage 50-16b for supplying the air is connected. The precision regulator 50-18b, a solenoid valve 50-20b, and a pressure gauge 50-22b are connected to the second pipe passage 50-16b. The solenoid valve 50-20b is a normally open valve, and the air flows through it when it is OFF. The pressure gauge 50-22b can measure the pressure inside the second pipe passage 50-16b. The second pipe passage 50-16b is supplied with an air pressure for cancelling its own weight m2g+m1g from the air cylinder 50-12 to the catalyst processing member 30. Note that m2g is a load above the load cell 50-14 and is included in the measurement by the load cell 50-14, and m1g is a load below the load cell 50-14 and is not included in the measurement by the load cell 50-14. As described above, the force applied to the shaft 50-1 from the air cylinder 50-12 can be measured by the load cell 50-14.

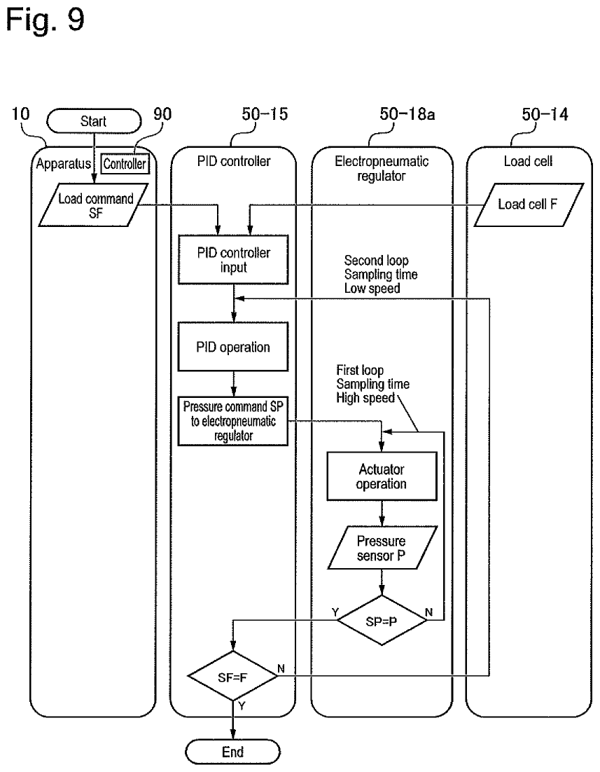

As one embodiment, a contact pressure between the catalyst processing member 30 and the wafer W can be PID controlled. FIG. 9 is a flowchart illustrating a procedure of PID controlling the contact pressure between the catalyst processing member 30 and the wafer W as one embodiment. As illustrated in the flowchart in FIG. 9, the PID controller 50-15 receives a load command SF from the controller 90 of the substrate processing apparatus 10. Meanwhile, the PID controller 50-15 receives a measured force F from the load cell 50-14. The PID controller 50-15 performs a PID operation for achieving the received load command SF inside the PID controller. The PID controller 50-15 provides a pressure command SP to the electropneumatic regulator 50-18a based on the PID operation result. The electropneumatic regulator 50-18a that has received the pressure command SP operates an internal actuator to discharge the air of a predetermined pressure P. Note that the electropneumatic regulator 50-18a internally holds a pressure sensor, and is feedback-controlled such that the air pressure P discharged from the electropneumatic regulator 50-18a becomes equal to the pressure command SP. Such a feedback control is performed by a sampling time at a relatively high speed. The air discharged by the electropneumatic regulator 50-18a is supplied to the air cylinder 50-12 to drive the air cylinder. The force F generated by the air cylinder 50-12 is measured by the load cell 50-14. The PID controller 50-15 compares the measurement value F received from the load cell 50-14 with the load command SF received from the controller 90, and repeats the process at and after the PID operation until they become equal. Such a feedback control is performed in a sampling time at a lower speed than the above-described internal feedback control of the electropneumatic regulator 50-18a. Thus, monitoring and feedback-controlling the pressing force of the catalyst processing member 30 against the wafer W using the load cell 50-14 and the PID controller 50-15 ensures always maintaining optimum pressing force. Note that, to control the driving speed of the air cylinder 50-12, it is possible to vary the load command in phases (for example, at every 0.1 second) to reach the final load command SF.

As illustrated in FIG. 2, the conditioning member 60 is configured to condition the surface of the catalyst 31 at a predetermined timing. The conditioning member 60 is arranged outside the wafer W held on the stage 20. The catalyst 31 held by the catalyst processing member 30 can be arranged on the conditioning member 60 by the swing arm 50. In this embodiment, the conditioning member 60 includes a scrub cleaning member 61. The scrub cleaning member 61 is configured of a sponge, a brush, or the like, and scrubs and cleans the catalyst 31 in the presence of the cleaning liquid supplied from a cleaning liquid supply member 62. The contact between the catalyst processing member 30 and the scrub cleaning member 61 at this time is made by the vertical motion of a side of the catalyst processing member 30 or the scrub cleaning member 61. At the time of conditioning, at least one of the catalyst processing member 30 or the scrub cleaning member 61 is caused to make a relative movement, such as a rotation. This ensures recovering the surface of the catalyst 31 on which the etching product is attached to an active state, and moreover, ensures reducing the damage on the region to be processed of the wafer W from the etching product.

Not limited to the above-described configuration, various kinds of configurations can be employed for the conditioning member 60. For example, while water may be basically used as the cleaning liquid in this scrub cleaning member 61, there is a case where the removal is difficult only by scrub cleaning depending on the etching product. In such a case, a chemical liquid that can remove the etching product may be supplied as the cleaning liquid. For example, when the etching product is silicate (SiO₂), hydrofluoric acid may be used as the chemical liquid. Alternatively, the conditioning member 60 may include an electrolytic regeneration unit configured to remove the etching product on the catalyst 31 surface using an electrolytic action. Specifically, the electrolytic regeneration unit includes an electrode configured to be electrically connectable with the catalyst 31, and is configured to remove the etching product attached on the surface of the catalyst 31 by applying a voltage between the catalyst and the electrode.

Alternatively, the conditioning member 60 may include a plating regeneration unit configured to regenerate the catalyst 31 by newly plating the catalyst 31. This plating regeneration unit includes an electrode configured to be electrically connectable with the catalyst 31, and is configured to regenerate plating on the surface of the catalyst 31 by applying a voltage between the catalyst 31 and the electrode in a state where the catalyst 31 is immersed in a liquid containing the catalyst for regeneration.

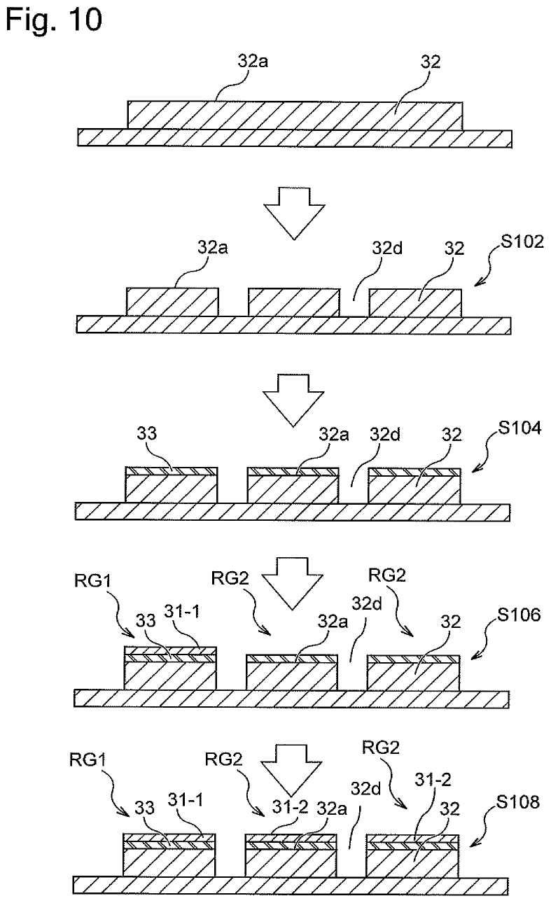

Next, a method for fabricating the catalyst processing member 30 will be described. FIG. 10 is a drawing illustrating the method for fabricating the catalyst processing member as one embodiment. Note that the following description illustrates the example of forming the grid-shaped grooves 32d on the base material 32, but the same applies to the case of forming grooves in other forms. As illustrated in FIG. 10, the method for fabricating the catalyst processing member 30, first, forms the grid-shaped grooves 32d on the processing surface 32a of the base material 32 (a forming step S102). The groove 32d has a role to quickly flow the process liquid supplied from the center of the base material 32 over the entire processing surface 32a. Note that while this embodiment has described the groove having an orthogonal shape with a width of an opening portion of the groove and a width of a bottom portion of the groove being equal in a longitudinal sectional shape as one example of the groove 32d, but it is not limited to this. The groove 32d can be formed into a tapered groove or a trapezoidal groove with the groove bottom portion width larger than the groove opening portion width or the groove bottom portion width smaller than the groove opening portion width in the longitudinal cross-section.

Subsequently, the method for fabricating the catalyst processing member 30 selectively applies an adhesive 33 on portions where the grooves 32d are absent on the processing surface 32a (projecting portions on the processing surface 32a) (an applying step S104). Note that the applying step S104 may apply the adhesive 33 on the catalyst 31 side instead of the processing surface 32a side.

Subsequently, the method for fabricating the catalyst processing member 30 adheres the foil, film, or plate-form first catalyst 31-1 with a micrometer order thickness on the projecting portions in a first region RG1 of the processing surface 32a via the adhesive 33 (a first adhering step S106). Subsequently, the method for fabricating the catalyst processing member 30 adheres the foil, film, or plate-form second catalyst 31-2 with a micrometer order thickness on the projecting portions in a second region RG2 of the processing surface 32a via the adhesive 33 (a second adhering step S108). With this embodiment, the different types of the catalysts 31-1 and 31-2 can be formed in a plurality of the regions RG1 and RG2 sectioned by the groove 32d, and as a result, the heterogeneous films can be uniformly planarized and removed.

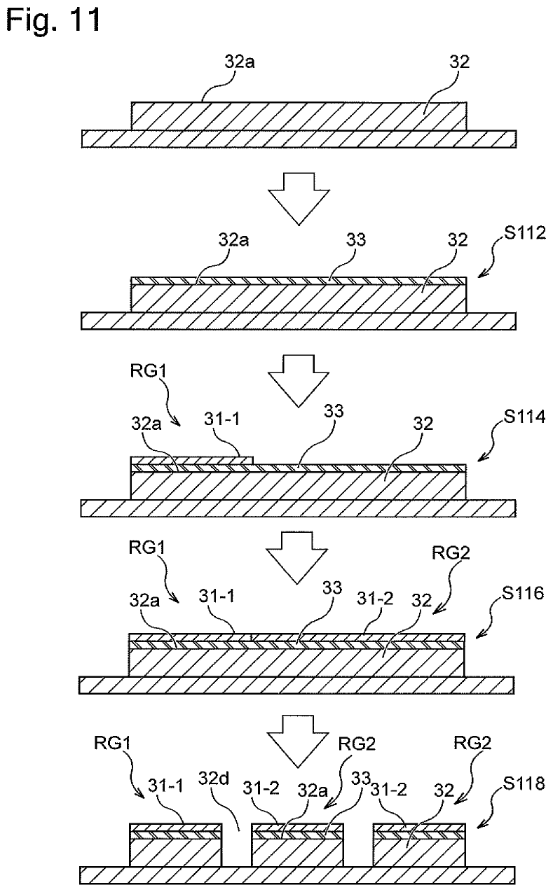

Next, another method for fabricating the catalyst processing member 30 will be described. FIG. 11 is a drawing illustrating a method for fabricating the catalyst processing member as one embodiment. As illustrated in FIG. 11, the method for fabricating the catalyst processing member 30, first, applies the adhesive 33 on the processing surface 32a of the base material 32 (an applying step S112). Note that the applying step S112 may apply the adhesive 33 on the catalyst 31 side instead of the processing surface 32a side.

Subsequently, the method for fabricating the catalyst processing member 30 adheres the foil, film, or plate-form first catalyst 31-1 with a micrometer order thickness in the first region RG1 on the processing surface 32a via the adhesive 33 (a first adhering step S114). Subsequently, the method for fabricating the catalyst processing member 30 adheres the foil, film, or plate-form second catalyst 31-2 with a micrometer order thickness in the second region RG2 on the processing surface 32a via the adhesive 33 (a second adhering step S116). Subsequently, the method for fabricating the catalyst processing member 30 forms the grid-shaped grooves 32d on the first catalyst 31-1, the second catalyst 31-2, the adhesive 33, and the processing surface 32a (a forming step S118). The forming step S118 can form the grooves 32d by, for example, a laser. The forming step S118 can form the grooves 32d by machining or molding with a mold, not limited to the laser processing. This embodiment ensures quickly fabricating the catalyst processing member 30 with a little process. This embodiment ensures forming the different types of the catalysts 31-1 and 31-2 in the plurality of regions RG1 and RG2 sectioned by the grooves 32d, and as a result, the heterogeneous films can be uniformly planarized and removed.

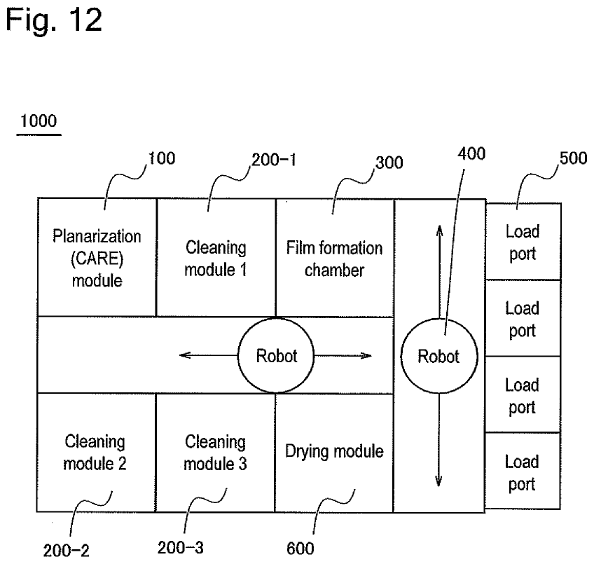

FIG. 12 is a plan view illustrating a schematic configuration of the substrate processing system as one embodiment. An illustrated substrate processing system 1000 includes a CARE module 100 configured to perform an etching process on a substrate as described herein, a plurality of cleaning modules 200 for cleaning the substrate, a film formation chamber 300, robots 400 as conveyance mechanisms for the substrate, load ports 500 of the substrate, and a drying module 600. In such a system configuration, the wafer W to be processed is put in the load port 500. The wafer loaded in the load port 500 is conveyed to the film formation chamber 300 by the robot 400, and the deposition process is performed in the film formation chamber 300. The film formation chamber 300 can be a chemical vapor deposition (CVD) device, a sputtering device, a plating device, a coater device, and the like. The wafer W on which the deposition has been performed is conveyed to a first cleaning module 200-1 by the robot 400 and is cleaned. Afterwards, the wafer W is conveyed to the planarization module 100, that is, the CARE processing module as described herein, and the planarization process is performed. Afterwards, the wafer W is conveyed to a second cleaning module 200-2 and/or a third cleaning module 200-3 and is cleaned. The wafer W on which the cleaning process has been performed is conveyed to the drying module 600 and is dried. The dried wafer W is returned to the load port 500 again. In this system, the deposition process and the planarization process of the wafer W can be executed in one system, and therefore, an installation area can be efficiently utilized. The conveyance mechanism is configured to convey a substrate in a wet state and a substrate in a dry state separately.

The following describes Examples based on experiments of removing and planarizing various kinds of heterogeneous films using the substrate processing apparatus 10 of this embodiment.

### Example 1

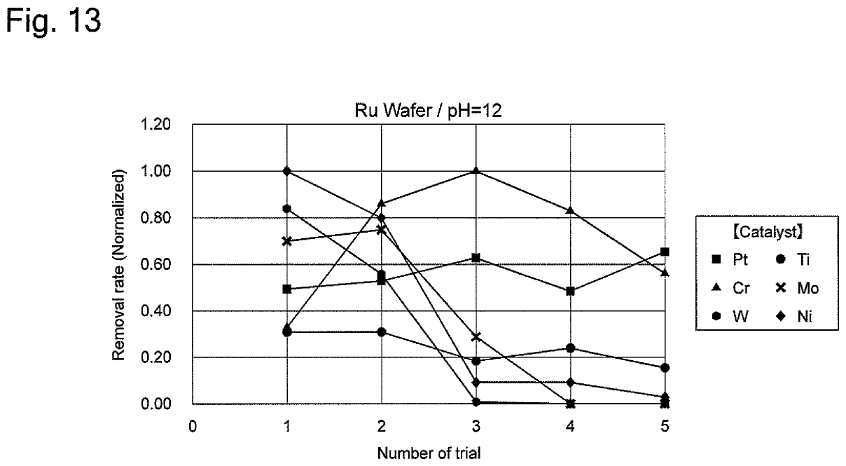

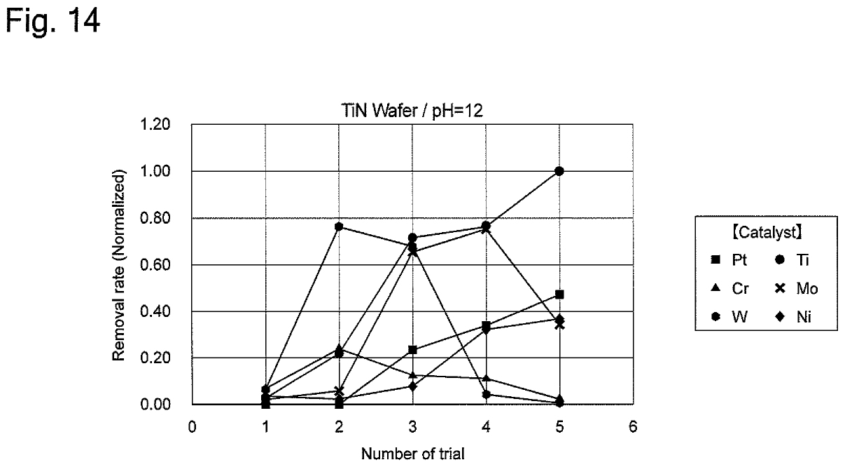

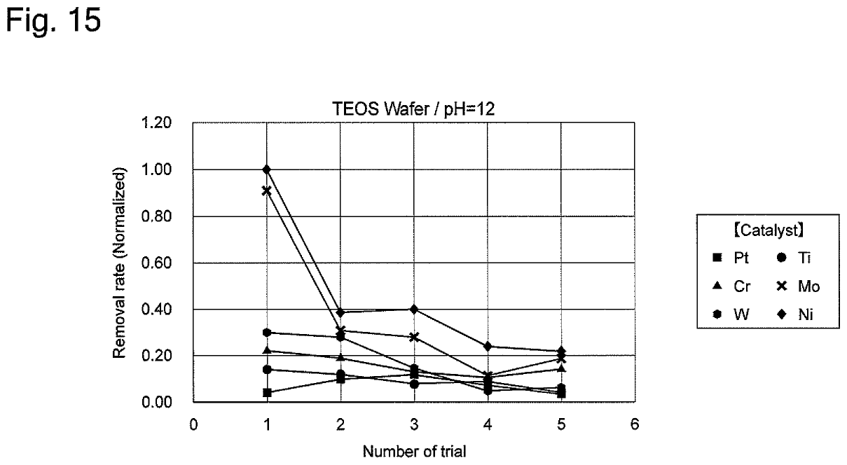

In Example 1, heterogeneous films made of a Ru and SiO₂ film and an alloy film containing Ti, such as TiN, or a Ti film were removed and planarized under a condition where a chemical liquid has pH=12 obtained by mixing inorganic base and hydrogen peroxide. FIG. 13 is a graph illustrating removal rates when the Ru film formed on the surface to be processed of the wafer W is planarized using various kinds of catalysts under a condition where a chemical liquid has pH=12. In FIG. 13, the vertical axis indicates a normalized removal rate and the horizontal axis indicates the number of trials. As illustrated in FIG. 13, upon removing Ru, it is preferred to dispose Cr, Pt, W, Mo or an alloy containing them on the base material from the aspect of removal rate. FIG. 14 is a graph illustrating removal rates when the TIN film formed on the surface to be processed of the wafer W is planarized using various kinds of catalysts under a condition where a chemical liquid has pH=12. In FIG. 14, the vertical axis indicates a normalized removal rate and the horizontal axis indicates the number of trials. As illustrated in FIG. 14, upon removing TiN, it is preferred to dispose Ti, Cr, Mo, W, Pt, Ni or an alloy containing them on the base material from the aspect of removal rate. FIG. 15 is a graph illustrating removal rates when the TEOS film formed on the surface to be processed of the wafer W is planarized using various kinds of catalysts under a condition where a chemical liquid has pH=12. In FIG. 15, the vertical axis indicates a normalized removal rate and the horizontal axis indicates the number of trials. As illustrated in FIG. 15, upon removing the SiO₂ film, it is preferred to dispose Ni, Mo, or an alloy containing them on the base material from the aspect of removal rate. Since corrosions of Mo and W easily progress under a basic condition, it is particularly preferred to alloy them.

### Example 2

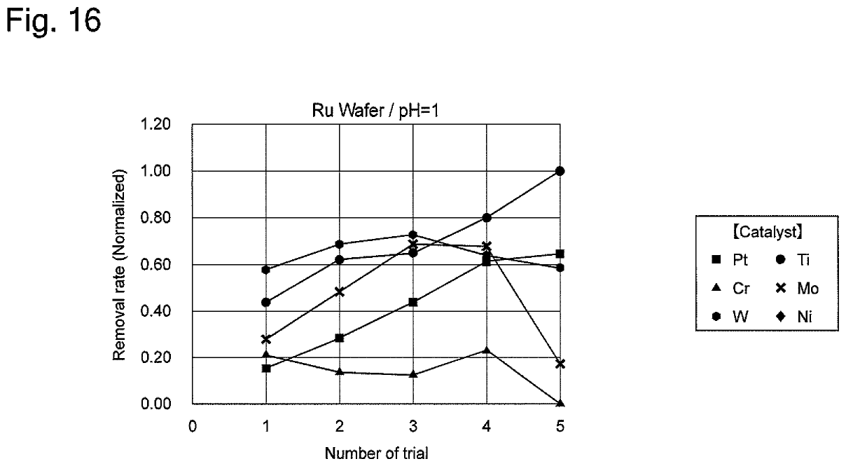

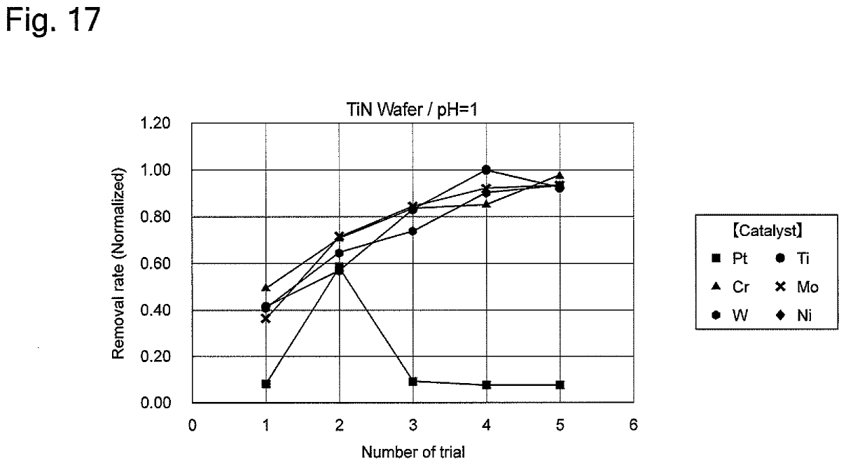

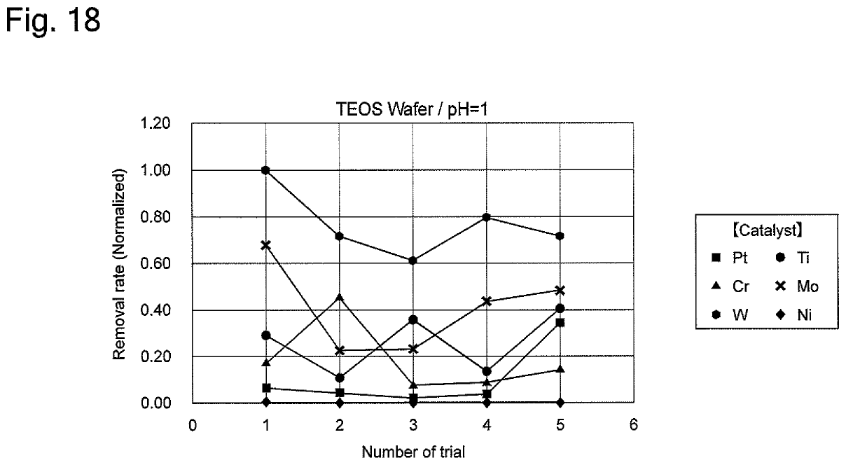

In Example 2, heterogeneous films made of a Ru and SiO₂ film and an alloy film containing Ti, such as TiN, or a Ti film were removed and planarized under a condition where a chemical liquid has pH=1 obtained by mixing inorganic acid hydrogen peroxide. FIG. 16 is a graph illustrating removal rates when the Ru film formed on the surface to be processed of the wafer W is planarized using various kinds of catalysts under a condition where a chemical liquid has pH=1. In FIG. 16, the vertical axis indicates a normalized removal rate and the horizontal axis indicates the number of trials. As illustrated in FIG. 16, upon removing Ru, it is preferred to dispose Ti, Pt, W, Mo or an alloy containing them on the base material from the aspect of removal rate. FIG. 17 is a graph illustrating removal rates when the TiN film formed on the surface to be processed of the wafer W is planarized using various kinds of catalysts under a condition where a chemical liquid has pH=1. In FIG. 17, the vertical axis indicates a normalized removal rate and the horizontal axis indicates the number of trials. As illustrated in FIG. 17, upon removing TiN, it is preferred to dispose Ti, Cr, Mo, W, or an alloy containing them on the base material from the aspect of removal rate. FIG. 18 is a graph illustrating removal rates when the TEOS film formed on the surface to be processed of the wafer W is planarized using various kinds of catalysts under a condition where a chemical liquid has pH=1. In FIG. 18, the vertical axis indicates a normalized removal rate and the horizontal axis indicates the number of trials. As illustrated in FIG. 18, upon removing the SiO₂ film, it is preferred to dispose W or an alloy containing it on the base material from the aspect of removal rate. Since corrosion of Mo easily progresses under an acidic condition, it is particularly preferred to alloy it.

### Example 3

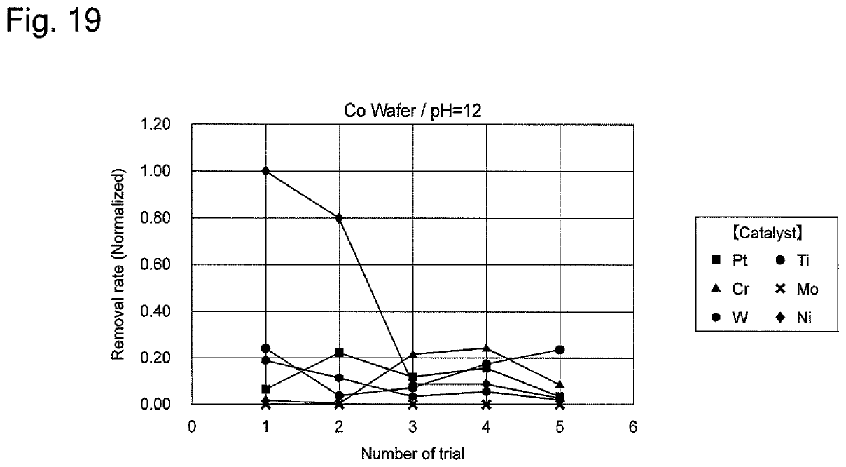

In Example 3, heterogeneous films made of a Co and SiO₂ film and an alloy film containing Ti, such as TiN, or a Ti film were removed and planarized. Since Co easily corrodes and dissolves under an acidic condition or a neutral condition, it is difficult to remove it under the acidic condition, and it is preferred to remove and planarize under a condition where a chemical liquid has pH=12 obtained by mixing inorganic base and hydrogen peroxide. FIG. 19 is a graph illustrating removal rates when the Co film formed on the surface to be processed of the wafer W is planarized using various kinds of catalysts under a condition where a chemical liquid has pH=12. In FIG. 19, the vertical axis indicates a normalized removal rate and the horizontal axis indicates the number of trials. As illustrated in FIG. 19, upon removing Co, it is preferred to dispose Ni or an alloy containing Ni on the base material from the aspect of removal rate. As illustrated in FIG. 14, upon removing TiN, it is preferred to dispose Ti, Cr, Mo, W, Pt, Ni or an alloy containing them on the base material from the aspect of removal rate. As illustrated in FIG. 15, upon removing the SiO₂ film, it is preferred to dispose Ni, Mo, or an alloy containing them on the base material from the aspect of removal rate. Since corrosions of Mo and W easily progress under a basic condition, it is particularly preferred to alloy them.

In the foregoing, several embodiments of the present invention have been described above in order to facilitate understanding of the present invention without limiting the present invention. The present invention can be changed or improved without departing from the gist thereof, and of course, the equivalents of the present invention are included in the present invention. It is possible to arbitrarily combine or omit respective constituent elements described in the claims and specification in a range in which at least a part of the above-described problems can be solved, or a range in which at least a part of the effects can be exhibited.

This application discloses a substrate processing apparatus including: a stage for holding a substrate with a surface to be processed upward; a catalyst processing member for processing the surface to be processed of the substrate using a catalyst; a pressing mechanism for pressing the catalyst processing member against the surface to be processed of the substrate; a relative motion mechanism for causing the catalyst processing member and the substrate to make a relative movement: and a supply mechanism for supplying a process liquid to the surface to be processed of the substrate as one embodiment. The catalyst processing member has a processing surface opposed to the surface to be processed of the substrate, and includes a base material on which a groove in a grid shape, a radial shape, a concentric shape, or a shape composed thereof is formed on the processing surface and the catalyst held on the processing surface. The processing surface of the base material includes a plurality of regions sectioned by the groove. The catalyst processing member holds different types of catalysts in the plurality of regions.

Furthermore, this application discloses the substrate processing apparatus in which the groove is formed into a shape of an orthogonal groove, a tapered groove, or a trapezoidal groove, and the catalyst processing member holds the catalyst in a region where the groove is absent on the processing surface of the base material, as one embodiment.

Furthermore, this application discloses the substrate processing apparatus in which the catalyst held on the processing surface is a foil, film, or plate-form catalyst with a micrometer order thickness, as one embodiment.

Furthermore, this application discloses the substrate processing apparatus in which the different types of the catalysts include a first catalyst and a second catalyst, the processing surface of the base material has a radial groove formed thereon, and the catalyst processing member holds the first catalyst and the second catalyst alternately in a circumferential direction in a plurality of regions sectioned by the radial groove, as one embodiment.

Furthermore, this application discloses the substrate processing apparatus in which the different types of the catalysts include a first catalyst and a second catalyst, the processing surface of the base material has a concentric groove formed thereon, and the catalyst processing member holds the first catalyst and the second catalyst alternately in a radial direction in a plurality of regions sectioned by the concentric groove, as one embodiment.

Furthermore, this application discloses the substrate processing apparatus in which the different types of the catalysts include a first catalyst and a second catalyst, the processing surface of the base material has a grid-shaped groove formed thereon, and the catalyst processing member holds the first catalyst and the second catalyst alternately in a longitudinal direction and a lateral direction in a plurality of regions sectioned by the grid-shaped groove, as one embodiment.

Furthermore, this application discloses the substrate processing apparatus in which the different types of the catalysts include a first catalyst and a second catalyst, the processing surface of the base material has a radial groove formed thereon, and a grid-shaped groove is formed in each of a plurality of regions sectioned by the radial groove, and the catalyst processing member holds the first catalyst and the second catalyst alternately in a circumferential direction in a plurality of regions sectioned by the radial groove, as one embodiment.

Furthermore, this application discloses the substrate processing apparatus in which the catalyst processing member holds the different types of the catalysts on the processing surface of the base material at an area ratio with which a plurality of process target materials are uniformly removable corresponding to an area ratio of the plurality of process target materials on the surface to be processed of the substrate and removal rates of the plurality of process target materials by the respective catalysts, as one embodiment.

Furthermore, this application discloses a method for fabricating a catalyst processing member for processing a surface to be processed of a substrate using a catalyst as one embodiment. The method includes: a forming step of forming a groove in a grid shape, a concentric shape, a radial shape, or a shape obtained by combining these on a processing surface of a base material; an applying step of selectively applying an adhesive on a portion where the groove of the processing surface is absent, a first adhering step of adhering a foil, film, or plate-form first catalyst with a micrometer order thickness on a first region of the processing surface via the adhesive, and a second adhering step of adhering a foil, film, or plate-form second catalyst with a micrometer order thickness on a second region of the processing surface via the adhesive.

Furthermore, this application discloses a method for fabricating a catalyst processing member for processing a surface to be processed of a substrate using a catalyst as one embodiment. The method includes: an applying step of applying an adhesive on a processing surface of a base material; a first adhering step of adhering a foil, film, or plate-form first catalyst with a micrometer order thickness on a first region of the processing surface via the adhesive; a second adhering step of adhering a foil, film, or plate-form second catalyst with a micrometer order thickness on a second region of the processing surface via the adhesive; and a forming step of forming a groove in a grid shape, a concentric shape, a radial shape, or a shape obtained by combining these on the first catalyst, the second catalyst, the adhesive, and the processing surface.

### REFERENCE SIGNS LIST

10 . . . substrate processing apparatus
20 . . . stage
21 . . . wall member
22 . . . rotation drive mechanism
30 . . . catalyst processing member
30-32 . . . gimbal mechanism
30-40 . . . process liquid supply passage
30-42 . . . supply port
30-49 . . . catalyst electrode
30-50 . . . counter electrode
31 . . . catalyst
31-1 . . . first catalyst
31-2 . . . second catalyst
32 . . . base material
32a . . . processing surface
32b . . . groove
32c . . . groove
32d . . . groove
33 . . . adhesive
35 . . . rotation drive mechanism
40 . . . process liquid supply member
50 . . . swing arm
50-1 . . . shaft
50-10 . . . rotation motor
50-12 . . . elevating air cylinder
50-14 . . . load cell
50-15 . . . PID controller
50-18a . . . electropneumatic regulator
50-18b . . . precision regulator
50-2 . . . cover
50-20a . . . solenoid valve
50-20b . . . solenoid valve
50-22a . . . pressure gauge
50-22b . . . pressure gauge
504 . . . ball spline
50-6 . . . slip ring
50-8 . . . rotary joint
51 . . . rotation shaft
52 . . . pressing mechanism
53 . . . elevating mechanism
55 . . . swing mechanism
60 . . . conditioning member
61 . . . scrub cleaning member
62 . . . cleaning liquid supply member
90 . . . controller
100 . . . CARE module
200 . . . cleaning module
300 . . . film formation chamber
400 . . . robot
500 . . . load port
600 . . . drying module
1000 . . . substrate processing system
PL . . . process liquid
S102 . . . forming step
S104 . . . applying step
S106 . . . first adhering step
S108 . . . second adhering step
S112 . . . applying step
S114 . . . first adhering step
S116 . . . second adhering step
S118 . . . forming step
W . . . wafer

What is claimed is:

1. A substrate processing apparatus comprising:
a stage for holding a substrate with a surface to be processed upward;
a catalyst processing member for processing the surface to be processed of the substrate using a catalyst;
a pressing mechanism for pressing the catalyst processing member against the surface to be processed of the substrate;
a relative motion mechanism for causing the catalyst processing member and the substrate to make a relative movement; and
a supply mechanism for supplying a process liquid to the surface to be processed of the substrate, wherein
the catalyst processing member has a processing surface opposed to the surface to be processed of the substrate, and includes a base material on which a groove in a grid shape, a radial shape, a concentric shape, or a shape composed thereof is formed on the processing surface and the catalyst held on the processing surface,
the processing surface of the base material includes a plurality of regions sectioned by the groove, and
the catalyst processing member holds different types of catalysts in the plurality of regions.

2. The substrate processing apparatus according to claim 1, wherein
the groove is formed into a shape of an orthogonal groove, a tapered groove, or a trapezoidal groove, and
the catalyst processing member holds the catalyst in a region where the groove is absent on the processing surface of the base material.

3. The substrate processing apparatus according to claim 1, wherein
the catalyst held on the processing surface is a foil, film, or plate-form catalyst with a micrometer order thickness.

4. The substrate processing apparatus according to claim 3, wherein
the different types of the catalysts include a first catalyst and a second catalyst,
the processing surface of the base material has a radial groove formed thereon, and
the catalyst processing member holds the first catalyst and the second catalyst alternately in a circumferential direction in a plurality of regions sectioned by the radial groove.

5. The substrate processing apparatus according to claim 3, wherein
the different types of the catalysts include a first catalyst and a second catalyst,
the processing surface of the base material has a concentric groove formed thereon, and
the catalyst processing member holds the first catalyst and the second catalyst alternately in a radial direction in a plurality of regions sectioned by the concentric groove.

6. The substrate processing apparatus according to claim 3, wherein
the different types of the catalysts include a first catalyst and a second catalyst,
the processing surface of the base material has a grid-shaped groove formed thereon, and
the catalyst processing member holds the first catalyst and the second catalyst alternately in a longitudinal direction and a lateral direction in a plurality of regions sectioned by the grid-shaped groove.

7. The substrate processing apparatus according to claim 3, wherein
the different types of the catalysts include a first catalyst and a second catalyst,
the processing surface of the base material has a radial groove formed thereon, and a grid-shaped groove is formed in each of a plurality of regions sectioned by the radial groove, and
the catalyst processing member holds the first catalyst and the second catalyst alternately in a circumferential direction in a plurality of regions sectioned by the radial groove.

8. The substrate processing apparatus according to claim 3, wherein
the catalyst processing member holds the different types of the catalysts on the processing surface of the base material at an area ratio with which a plurality of process target materials are uniformly removable corresponding to an area ratio of the plurality of process target materials on the surface to be processed of the substrate and removal rates of the plurality of process target materials by the respective catalysts.

9. A method for fabricating a catalyst processing member for processing a surface to be processed of a substrate using a catalyst, the method comprising:
a forming step of forming a groove in a grid shape, a concentric shape, a radial shape, or a shape obtained by combining these on a processing surface of a base material;
an applying step of selectively applying an adhesive on a portion where the groove of the processing surface is absent;
a first adhering step of adhering a foil, film, or plate-form first catalyst with a micrometer order thickness on a first region of the processing surface via the adhesive; and
a second adhering step of adhering a foil, film, or plate-form second catalyst with a micrometer order thickness on a second region of the processing surface via the adhesive.

10. A method for fabricating a catalyst processing member for processing a surface to be processed of a substrate using a catalyst, the method comprising:
an applying step of applying an adhesive on a processing surface of a base material;
a first adhering step of adhering a foil, film, or plate-form first catalyst with a micrometer order thickness on a first region of the processing surface via the adhesive;
a second adhering step of adhering a foil, film, or plate-form second catalyst with a micrometer order thickness on a second region of the processing surface via the adhesive; and
a forming step of forming a groove in a grid shape, a concentric shape, a radial shape, or a shape obtained by combining these on the first catalyst, the second catalyst, the adhesive, and the processing surface.
